(19) United States
(12) Patent Application Publication
(10) Pub. No.: US 2025/0101569 A1
(43) Pub. Date: Mar. 27, 2025

(54) METHODS FOR CONTROLLING CRYSTALLINE PHASE OF MOLYBDENUM PRECURSORS AND RELATED COMPOSITIONS

(71) Applicant: ENTEGRIS, INC., Billerica, MA (US)

(72) Inventors: Robert Halbach, Burnet, TX (US); Trang Nguyen, Leander, TX (US); Pei Zhao, Leander, TX (US)

(21) Appl. No.: 18/898,556

(22) Filed: Sep. 26, 2024

Related U.S. Application Data
(60) Provisional application No. 63/540,514, filed on Sep. 26, 2023.

(51) Int. Cl. C23C 14/14; C23C 14/24

(52) U.S. Cl. CPC C23C 14/14; C23C 14/24

(57) ABSTRACT

Methods for controlling crystalline phase ratios of molybdenum precursors are provided. A method comprises vaporizing, at a first temperature and a first pressure, a molybdenum reagent in a first vessel to obtain a vaporized molybdenum precursor; flowing the vaporized molybdenum precursor from the first vessel to a second vessel; and condensing, at a second temperature and a second pressure, the vaporized molybdenum precursor in the second vessel to obtain a crystalline phase ratio of the molybdenum precursor.

### CROSS-REFERENCE TO RELATED APPLICATIONS

This application claims the benefit under 35 USC 119 of U.S. Provisional Patent Application No. 63/540,514, filed Sep. 26, 2023, the disclosure of which is hereby incorporated herein by reference in its entirety.

### FIELD

The present disclosure relates to methods for controlling crystalline phases of molybdenum precursors and related compositions.

### BACKGROUND

Controllable and predictable delivery of precursors to a tool used in semiconductor fabrication or other similar processes remains an ongoing challenge.

### SUMMARY

Some embodiments of the present disclosure relate to a method of vaporizing a molybdenum reagent to obtain a vaporized molybdenum precursor. In some embodiments, the method comprises vaporizing the molybdenum reagent at a first temperature and a first pressure in a first vessel; flowing the vaporized molybdenum precursor from the first vessel to a second vessel; and condensing, at a second temperature and a second pressure, the vaporized molybdenum precursor in the second vessel to obtain the molybdenum precursor. In some embodiments, the molybdenum precursor comprises a molybdenum pentachloride. In some embodiments, a crystalline phase ratio of the molybdenum pentachloride is sufficient for the molybdenum precursor to have a vapor pressure of 1 Pa to 1000 Pa at 25° C.

Some embodiments of the present disclosure relate to a composition comprising a molybdenum precursor comprising a molybdenum pentachloride. In some embodiments, a crystalline phase ratio of the molybdenum pentachloride is sufficient for the molybdenum precursor to have a vapor pressure of 1 Pa to 1000 Pa at 25° C.

Some embodiments of the present disclosure relate to a precursor vessel comprising a molybdenum precursor comprising a molybdenum pentachloride. In some embodiments, a crystalline phase ratio of the molybdenum pentachloride is sufficient for the molybdenum precursor to have a vapor pressure of 1 Pa to 1000 Pa at 25° C.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method for controlling crystalline phase of a molybdenum precursor, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “crystalline phase ratio” refers to a ratio of unit cell data as measured by single crystal X-ray diffraction to bulk data as measured by powder X-ray diffraction.

As used herein, the term “contacting” refers to bringing two or more components into immediate or close proximity, or into direct contact.

For example, and without limitation, the present disclosure relates to methods for vaporizing and/or condensing molybdenum precursors, compositions comprising molybdenum precursors, and precursor vessels.

Some embodiments relate to methods of vaporizing a molybdenum reagent to obtain a vaporized molybdenum precursor. Some embodiments, for example, provide methods for tuning a crystalline phase of a molybdenum precursor and related compositions. Some embodiments further provide methods for purifying and/or removing impurities from molybdenum precursors and compositions comprising purified molybdenum precursors. Such molybdenum precursors, when vaporized and used in semiconductor fabrication or other similar processes, can be supplied at a controllable constant flow rate. By modulating the crystalline phase of the molybdenum precursor and/or removing at least a portion of the impurities from molybdenum precursor, the vapor pressure of the molybdenum precursor can be stabilized, thereby minimizing fluctuations in the flow rate when delivering the vaporized molybdenum precursor to downstream tools.

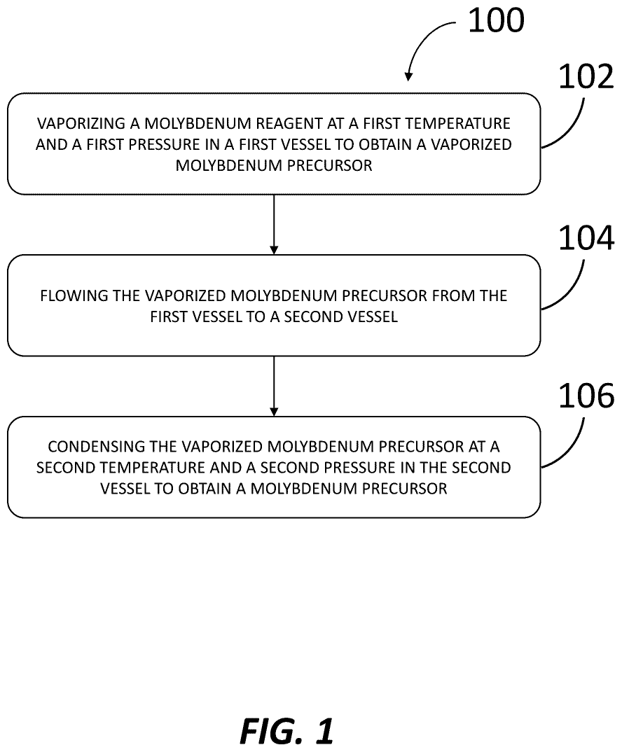

FIG. 1 depicts a schematic representation of a method according to some embodiments. In some embodiments, the method 100 for vaporizing a molybdenum precursor may comprise one or more of the following steps: a step 102 of vaporizing a molybdenum precursor in a first vessel at a first temperature and a first pressure to obtain a vaporized molybdenum precursor, a step 104 of flowing the vaporized molybdenum precursor from the first vessel to a second vessel, and a step 106 of condensing the vaporized molybdenum precursor in the second vessel at a second temperature and a second pressure to obtain a molybdenum precursor.

At step 102, in some embodiments, the molybdenum precursor is vaporized in a first vessel at a first temperature and a first pressure. In some embodiments, a first vessel may be obtained. In some embodiments, the first vessel comprises a solid reagent. In some embodiments, the solid reagent comprises at least one of a molybdenum precursor. In some embodiments, the molybdenum precursor comprises molybdenum pentachloride (MoCl₅). In some embodiments, the vaporizing comprises heating the first vessel to a first temperature. In some embodiments, the vaporizing comprises pressurizing or depressurizing the first vessel to a first pressure. In some embodiments, the vaporizing comprises heating the first vessel under vacuum. In some embodiments, the solid reagent is vaporized in the first vessel at a first temperature and a first pressure. In some embodiments, when the solid reagent is vaporized to obtain a vaporized molybdenum precursor, the step of vaporizing the molybdenum reagent is not performed. In some embodiments, when the molybdenum precursor is obtained a vaporized molybdenum precursor, the step of vaporizing the molybdenum precursor is not performed.

The molybdenum precursor may comprise a molybdenum compound. In some embodiments, the molybdenum precursor comprises a molybdenum pentachloride (MoCl₅). In some embodiments, the molybdenum precursor is present in at least one of a solid phase, a liquid phase, a gas/vapor phase, or any combination thereof. In some embodiments, the molybdenum precursor may be independently present in the first vessel in a solid phase, a gas phase, a vapor phase, or any combination thereof. In some embodiments, the solid phase is amorphous or crystalline. For example, in some embodiments, the solid phase of the molybdenum precursor is amorphous or crystalline. In some embodiments, the solid phase is as an isolated crystal. For example, in some embodiments, the molybdenum precursor is present as an isolated crystal.

In some embodiments, the molybdenum precursor comprises at least one impurity. In some embodiments, the molybdenum precursor comprises 1% to 15% by weight of at least one impurity based on a total weight of the molybdenum precursor, or any range or subrange between 1% and 15%. For example, in some embodiments, the molybdenum precursor comprises 1% to 14%, 1% to 13%, 1% to 12%, 1% to 11%, 1% to 10%, 1% to 9%, 1% to 8%, 1% to 7%, 1% to 6%, 1% to 5%, 1% to 4%, 1% to 3%, 1% to 2%, 2% to 15%, 3% to 15%, 4% to 15%, 5% to 15%, 6% to 15%, 7% to 15%, 8% to 15%, 9% to 15%, 10% to 15%, 11% to 15%, 12% to 15%, 13% to 15%, or 14% to 15% by weight of at least one impurity based on a total weight of the molybdenum precursor.

The first vessel may be configured to control temperature. The temperature of the first vessel may be controlled in any suitable manner. In some embodiments, a thermal jacket for heating and/or cooling is employed around the first vessel. In some embodiments, a ribbon heater is wound around the first vessel. In some embodiments, a block heater having a shape covering at least a major portion of the external surface of the first vessel is employed to heat the first vessel. In some embodiments, a resistive heater is employed to heat the first vessel. In some embodiments, a lamp heater is employed to heat the first vessel. In some embodiments, a heat transfer fluid at elevated temperature may be contacted with the exterior surface of the first vessel, to effect heating and/or cooling thereof. In some embodiments, the heating is conducted by infrared or other radiant energy being impinged on the first vessel. In some embodiments, the first vessel is cooled by a fluid, a fan, a direct thermoelectric device, or any combination thereof. It is to be appreciated that other heating and/or cooling devices and assemblies, and other configurations and arrangements of the heater and/or cooler may be employed herein without departing from the scope of this disclosure.

In some embodiments, the first temperature is a temperature of 50° C. to 200° C., or any range or subrange between 50° C. and 200° C. In some embodiments, the first temperature is a temperature of 60° C. to 200° C., 70° C. to 200° C., 80° C. to 200° C., 90° C. to 200° C., 100° C. to 200° C., 110° C. to 200° C., 120° C. to 200° C., 130° C. to 200° C., 140° C. to 200° C., 150° C. to 200° C., 160° C. to 200° C., 170° C. to 200° C., 180° C. to 200° C., or 190° C. to 200° C. In some embodiments, the first temperature is a temperature of 50° C. to 190° C., 50° C. to 180° C., 50° C. to 170° C., 50° C. to 160° C., 50° C. to 150° C., 50° C. to 140° C., 50° C. to 130° C., 50° C. to 120° C., 50° C. to 110° C., 50° C. to 100° C., 50° C. to 90° C., 50° C. to 80° C., 50° C. to 70° C., or 50° C. to 60° C. In some embodiments, the first temperature is a temperature of 50° C., 55° C., 60° C., 65° C., 70° C., 75° C., 80° C., 85° C., 90° C., 95° C., 100° C., 105° C., 110° C., 115° C., 120° C., 125° C., 130° C., 135° C., 140° C., 145° C., 150° C., 155° C., 160° C., 165° C., 170° C., 175° C., 180° C., 185° C., 190° C., 195° C., or 200° C.

The first vessel may be configured to control pressure. The pressure of the first vessel may be controlled in any suitable manner. In some embodiments, a gas inlet line is fluidly coupled to the first vessel. The gas inlet line may be configured to supply a pressurizing gas from a pressurizing gas source to the first vessel. Control of the pressurizing gas into the first vessel may be achieved by at least one of pressure regulators, needle valves, mass flow controllers, downstream pressure controllers, or any combination thereof. In some embodiments, the pressurizing gas comprises an inert gas. In some embodiments, the inert gas comprises at least one of helium, argon, nitrogen, or any combination thereof. In some embodiments, a vacuum line is fluidly coupled to the first vessel. The vacuum line may be configured to apply a vacuum to the first vessel. In some embodiments, the pumping speed is controlled by butterfly valves. It will be appreciated that other mechanisms for controlling the pressure of the first vessel may be employed herein without departing from the scope of this disclosure.

In some embodiments, the first pressure is a pressure of 0.01 Torr to 100 Torr, or any range or subrange between 0.01 Torr and 100 Torr. In some embodiments, the first pressure is a pressure of 0.01 Torr to 90 Torr, 0.01 Torr to 80 Torr, 0.01 Torr to 70 Torr, 0.01 Torr to 60 Torr, 0.01 Torr to 50 Torr, 0.01 Torr to 40 Torr, 0.01 Torr to 30 Torr, 0.01 Torr to 20 Torr, 0.01 Torr to 10 Torr, 0.01 Torr to 9 Torr, 0.01 Torr to 8 Torr, 0.01 Torr to 7 Torr, 0.01 Torr to 6 Torr, 0.01 Torr to 5 Torr, 0.01 Torr to 4 Torr, 0.01 Torr to 3 Torr, 0.01 Torr to 2 Torr, 0.01 Torr to 1 Torr, or 0.01 Torr to 0.05 Torr. In some embodiments, the first pressure is a pressure of 0.01 Torr to 100 Torr, 0.05 Torr to 100 Torr, 1 Torr to 100 Torr, 2 Torr to 100 Torr, 3 Torr to 100 Torr, 4 Torr to 100 Torr, 5 Torr to 100 Torr, 6 Torr to 100 Torr, 7 Torr to 100 Torr, 8 Torr to 100 Torr, 9 Torr to 100 Torr, 10 Torr to 100 Torr, 20 Torr to 100 Torr, 30 Torr to 100 Torr, 40 Torr to 100 Torr, 50 Torr to 100 Torr, 60 Torr to 100 Torr, 70 Torr to 100 Torr, 80 Torr to 100 Torr, or 90 Torr to 100 Torr. In some embodiments, the first pressure is a pressure of 0.01 Torr, 0.05 Torr, 1 Torr, 2 Torr, 3 Torr, 4 Torr, 5 Torr, 6 Torr, 7 Torr, 8 Torr, 9 Torr, 10 Torr, 20 Torr, 30 Torr, 40 Torr, 50 Torr, 60 Torr, 70 Torr, 80 Torr, 90 Torr, or 100 Torr.

The vaporized molybdenum precursor may comprise a vaporized molybdenum compound. In some embodiments, the vaporized molybdenum compound comprises a vaporized molybdenum pentachloride. In some embodiments, the vaporized molybdenum precursor comprises a vaporized molybdenum pentachloride. In some embodiments, the vaporized molybdenum precursor comprises at least one vaporized impurity. In some embodiments, the vaporized molybdenum precursor comprises 15% to 99% by volume of the vaporized molybdenum compound based on a total volume of the vaporized molybdenum precursor, or any range or subrange between 15% and 99%. For example, in some embodiments, the vaporized molybdenum precursor comprises 15% to 95%, 15% to 90%, 15% to 85%, 15% to 80%, 15% to 75%, 15% to 70%, 15% to 65%, 15% to 60%, 15% to 55%, 15% to 50%, 15% to 45%, 15% to 40%, 15% to 35%, 15% to 30%, 15% to 25%, 15% to 20%, 20% to 99%, 25% to 99%, 30% to 99%, 35% to 99%, 40% to 99%, 45% to 99%, 50% to 99%, 55% to 99%, 60% to 99%, 65% to 99%, 70% to 99%, 75% to 99%, 80% to 99%, 85% to 99%, 90% to 99%, or 95% to 99% by volume of the vaporized molybdenum compound based on the total volume of the vaporized molybdenum precursor.

In some embodiments, the vaporized molybdenum precursor comprises 1% to 15% by volume of at least one impurity based on a total volume of the vaporized molybdenum precursor, or any range or subrange between 1% and 15%. For example, in some embodiments, the vaporized molybdenum precursor comprises 1% to 14%, 1% to 13%, 1% to 12%, 1% to 11%, 1% to 10%, 1% to 9%, 1% to 8%, 1% to 7%, 1% to 6%, 1% to 5%, 1% to 4%, 1% to 3%, 1% to 2%, 2% to 15%, 3% to 15%, 4% to 15%, 5% to 15%, 6% to 15%, 7% to 15%, 8% to 15%, 9% to 15%, 10% to 15%, 11% to 15%, 12% to 15%, 13% to 15%, or 14% to 15% by volume of at least one impurity based on a total volume of the vaporized molybdenum precursor.

In some embodiments the method further comprises flowing the vaporized molybdenum precursor from the first vessel to a second vessel. In some embodiments, the flowing may comprise at least one of actuating a valve, delivering, discharging, drawing, drawing under vacuum, evacuating, feeding, injecting, passing, pumping, supplying, or otherwise providing the vaporized molybdenum precursor from the first vessel to a second vessel, or any combination thereof.

In some embodiments, the flowing comprises actuating a valve. In some embodiments, the flowing comprises delivering the vaporized molybdenum precursor from the first vessel to a second vessel. In some embodiments, the flowing comprises discharging the vaporized molybdenum precursor from the first vessel to a second vessel. In some embodiments, the flowing comprises drawing the vaporized molybdenum precursor from the first vessel to a second vessel. In some embodiments, the flowing comprises drawing the vaporized molybdenum precursor from the first vessel to a second vessel under a vacuum. In some embodiments, the flowing comprises evacuating the vaporized molybdenum precursor from the first vessel to a second vessel. In some embodiments, the flowing comprises feeding the vaporized molybdenum precursor from the first vessel to a second vessel. In some embodiments, the flowing comprises injecting the vaporized molybdenum precursor from the first vessel to a second vessel. In some embodiments, the flowing comprises passing the vaporized molybdenum precursor from the first vessel to a second vessel. In some embodiments, the flowing comprises pumping the vaporized molybdenum precursor from the first vessel to a second vessel. In some embodiments, the flowing comprises supplying the vaporized molybdenum precursor from the first vessel to a second vessel. It will be appreciated that the manner in which the molybdenum precursor is provided to a second vessel is not particularly limited and may include any suitable technique known in the art. In some embodiments, the method comprises cooling the second vessel. In some embodiment, the method comprises cooling the second vessel under vacuum.

In some embodiments, the method comprises condensing the vaporized molybdenum precursor at a second temperature and second pressure. In some embodiments, condensing comprises applying at least one condition sufficient to condense at least a portion of the vaporized molybdenum precursor in the second vessel. The at least one condition may be applied to at least one of the second vessel, the vaporized molybdenum precursor, the at least one impurity, or any combination thereof. In some embodiments, the condensing comprises cooling the second vessel and/or the vaporized molybdenum precursor and/or the least one impurity at or to a temperature sufficient to condense at least a portion of the molybdenum precursor in the second vessel. In some embodiments, the condensing comprises pressurizing the second vessel at or to a pressure sufficient to condense at least a portion of the vaporized molybdenum precursor in the second vessel. In some embodiments, the condensing comprises depressurizing the second vessel at or to a pressure sufficient to condense at least a portion of the vaporized molybdenum precursor in the second vessel. The condensing may comprise cooling the second vessel and/or the vaporized molybdenum precursor. In some embodiments, the condensing may comprise pressurizing or depressurizing the second vessel.

In some embodiments, at least a portion of the vaporized molybdenum precursor is condensed. In some embodiments, the at least one impurity vapor is not condensed. In some embodiments, the condensing is sufficient to separate at least a portion of the vaporized molybdenum precursor from the at least one impurity vapor.

The second vessel may be configured to control temperature. The temperature of the second vessel may be controlled in any suitable manner. In some embodiments, a thermal jacket for heating and/or cooling is employed around the second vessel. In some embodiments, a ribbon heater is wound around the second vessel. In some embodiments, a block heater having a shape covering at least a major portion of the external surface of the second vessel is employed to heat the second vessel. In some embodiments, a resistive heater is employed to heat the second vessel. In some embodiments, a lamp heater is employed to heat the second vessel. In some embodiments, a heat transfer fluid at elevated temperature may be contacted with the exterior surface of the second vessel, to effect heating and/or cooling thereof. In some embodiments, the heating is conducted by infrared or other radiant energy being impinged on the second vessel. In some embodiments, the second vessel is cooled by a fluid, a fan, a direct thermoelectric device, or any combination thereof. It is to be appreciated that other heating and/or cooling devices and assemblies, and other configurations and arrangements of the heater and/or cooler may be employed herein without departing from the scope of this disclosure.

In some embodiments, the second temperature is a temperature of 50° C. to 200° C. or any range or subrange between 50° C. and 200° C. In some embodiments, the second temperature is a temperature of 60° C. to 200° C., 70° C. to 200° C., 80° C. to 200° C., 90° C. to 200° C., 100° C. to 200° C., 110° C. to 200° C., 120° C. to 200° C., 130° C. to 200° C., 140° C. to 200° C., 150° C. to 200° C., 160° C. to 200° C., 170° C. to 200° C., 180° C. to 200° C., or 190° C. to 200° C. In some embodiments, the second temperature is a temperature of 50° C. to 190° C., 50° C. to 180° C., 50° C. to 170° C., 50° C. to 160° C., 50° C. to 150° C., 50° C. to 140° C., 50° C. to 130° C., 50° C. to 120° C., 50° C. to 110° C., 50° C. to 100° C., 50° C. to 90° C., 50° C. to 80° C., 50° C. to 70° C., or 50° C. to 60° C. In some embodiments, the second temperature is a temperature of 50° C., 55° C., 60° C., 65° C., 70° C., 75° C., 80° C., 85° C., 90° C., 95° C., 100° C., 105° C., 110° C., 115° C., 120° C., 125° C., 130° C., 135° C., 140° C., 145° C., 150° C., 155° C., 160° C., 165° C., 170° C., 175° C., 180° C., 185° C., 190° C., 195° C., or 200° C.

The second vessel may be configured to control pressure. The pressure of the second vessel may be controlled in any suitable manner. In some embodiments, a gas inlet line is fluidly coupled to the second vessel. The gas inlet line may be configured to supply a pressurizing gas from a pressurizing gas source to the second vessel. Control of the pressurizing gas into the second vessel may be achieved by at least one of pressure regulators, needle valves, mass flow controllers, downstream pressure controllers, or any combination thereof. In some embodiments, the pressurizing gas comprises an inert gas. In some embodiments, the inert gas comprises at least one of helium, argon, nitrogen, or any combination thereof. In some embodiments, a vacuum line is fluidly coupled to the second vessel. The vacuum line may be configured to apply a vacuum to the second vessel. In some embodiments, the pumping speed is controlled by butterfly valves. It will be appreciated that other mechanisms for controlling the pressure of the second vessel may be employed herein without departing from the scope of this disclosure.

In some embodiments, the second pressure is a pressure of 0.01 Torr to 100 Torr, or any range or subrange between 0.01 Torr and 100 Torr. In some embodiments, the second pressure is a pressure of 0.01 Torr to 90 Torr, 0.01 Torr to 80 Torr, 0.01 Torr to 70 Torr, 0.01 Torr to 60 Torr, 0.01 Torr to 50 Torr, 0.01 Torr to 40 Torr, 0.01 Torr to 30 Torr, 0.01 Torr to 20 Torr, 0.01 Torr to 10 Torr, 0.01 Torr to 9 Torr, 0.01 Torr to 8 Torr, 0.01 Torr to 7 Torr, 0.01 Torr to 6 Torr, 0.01 Torr to 5 Torr, 0.01 Torr to 4 Torr, 0.01 Torr to 3 Torr, 0.01 Torr to 2 Torr, 0.01 Torr to 1 Torr, or 0.01 Torr to 0.05 Torr. In some embodiments, the second pressure is a pressure of 0.01 Torr to 100 Torr, 0.05 Torr to 100 Torr, 1 Torr to 100 Torr, 2 Torr to 100 Torr, 3 Torr to 100 Torr, 4 Torr to 100 Torr, 5 Torr to 100 Torr, 6 Torr to 100 Torr, 7 Torr to 100 Torr, 8 Torr to 100 Torr, 9 Torr to 100 Torr, 10 Torr to 100 Torr, 20 Torr to 100 Torr, 30 Torr to 100 Torr, 40 Torr to 100 Torr, 50 Torr to 100 Torr, 60 Torr to 100 Torr, 70 Torr to 100 Torr, 80 Torr to 100 Torr, or 90 Torr to 100 Torr. In some embodiments, the second pressure is a pressure of 0.01 Torr, 0.05 Torr, 1 Torr, 2 Torr, 3 Torr, 4 Torr, 5 Torr, 6 Torr, 7 Torr, 8 Torr, 9 Torr, 10 Torr, 20 Torr, 30 Torr, 40 Torr, 50 Torr, 60 Torr, 70 Torr, 80 Torr, 90 Torr, or 100 Torr.

In some embodiments, the first temperature is different from the second temperature. In some embodiments, the first pressure is different from the second pressure. In some embodiments, the first temperature and the first pressure are different from the second temperature and the second pressure.

Some embodiments relate to compositions comprising a molybdenum precursor. In some embodiments, the molybdenum precursor comprises a molybdenum pentachloride. Some embodiments relate to precursor vessels comprising a molybdenum precursor. In some embodiments, the precursor vessels comprise a molybdenum precursor comprising a molybdenum pentachloride.

In some embodiments, the molybdenum precursor comprises triclinic molybdenum pentachloride crystals. In some embodiments, the molybdenum precursor comprises monoclinic molybdenum pentachloride crystals. In some embodiments, the molybdenum precursor comprises orthorhombic molybdenum pentachloride crystals. In some embodiments, the molybdenum precursor comprises tetragonal molybdenum pentachloride crystals. In some embodiments, the molybdenum precursor comprises hexagonal molybdenum pentachloride crystals. In some embodiments, the molybdenum precursor comprises cubic molybdenum pentachloride crystals.

In some embodiments, the molybdenum precursor comprises any one of triclinic molybdenum pentachloride crystals, monoclinic molybdenum pentachloride crystals, orthorhombic molybdenum pentachloride crystals, tetragonal molybdenum pentachloride crystals, hexagonal molybdenum pentachloride crystals, or cubic molybdenum pentachloride crystals. In some embodiments, the molybdenum precursor comprises any two of triclinic molybdenum pentachloride crystals, monoclinic molybdenum pentachloride crystals, orthorhombic molybdenum pentachloride crystals, tetragonal molybdenum pentachloride crystals, hexagonal molybdenum pentachloride crystals, and cubic molybdenum pentachloride crystals. In some embodiments, the molybdenum precursor comprises any three of triclinic molybdenum pentachloride crystals, monoclinic molybdenum pentachloride crystals, orthorhombic molybdenum pentachloride crystals, tetragonal molybdenum pentachloride crystals, hexagonal molybdenum pentachloride crystals, and cubic molybdenum pentachloride crystals. In some embodiments, the molybdenum precursor comprises any four of triclinic molybdenum pentachloride crystals, monoclinic molybdenum pentachloride crystals, orthorhombic molybdenum pentachloride crystals, tetragonal molybdenum pentachloride crystals, hexagonal molybdenum pentachloride crystals, and cubic molybdenum pentachloride crystals. In some embodiments, the molybdenum precursor comprises any five of triclinic molybdenum pentachloride crystals, monoclinic molybdenum pentachloride crystals, orthorhombic molybdenum pentachloride crystals, tetragonal molybdenum pentachloride crystals, hexagonal molybdenum pentachloride crystals, and cubic molybdenum pentachloride crystals. In some embodiments, the molybdenum precursor comprises all six of triclinic molybdenum pentachloride crystals, monoclinic molybdenum pentachloride crystals, orthorhombic molybdenum pentachloride crystals, tetragonal molybdenum pentachloride crystals, hexagonal molybdenum pentachloride crystals, and cubic molybdenum pentachloride crystals.

In some embodiments, the molybdenum precursor has a crystalline phase ratio which is sufficient for the molybdenum precursor to have a vapor pressure of 1 Pa to 1000 Pa at 25° C., or any range or subrange between 1 Pa to 1000 Pa. In some embodiments, the molybdenum precursor has a crystalline phase ratio which is sufficient for the molybdenum precursor to have a vapor pressure of 1 Pa to 900 Pa at 25° C., 1 Pa to 800 Pa at 25° C., 1 Pa to 700 Pa at 25° C., 1 Pa to 600 Pa at 25° C., 1 Pa to 500 Pa at 25° C., 1 Pa to 400 Pa at 25° C., 1 Pa to 300 Pa at 25° C., 1 Pa to 200 Pa at 25° C., 1 Pa to 100 Pa at 25° C., 1 Pa to 90 Pa at 25° C., 1 Pa to 80 Pa at 25° C., 1 Pa to 70 Pa at 25° C., 1 Pa to 60 Pa at 25° C., 1 Pa to 50 Pa at 25° C., 1 Pa to 40 Pa at 25° C., 1 Pa to 30 Pa at 25° C., 1 Pa to 20 Pa at 25° C., or 1 Pa to 10 Pa at 25° C.

In some embodiments, the molybdenum precursor has a crystalline phase ratio which is sufficient for the molybdenum precursor to have a vapor pressure of 10 Pa to 1000 Pa at 25° C., 20 Pa to 1000 Pa at 25° C., 30 Pa to 1000 Pa at 25° C., 40

Pa to 1000 Pa at 25° C., 50 Pa to 1000 Pa at 25° C., 60 Pa to 1000 Pa at 25° C., 70 Pa to 1000 Pa at 25° C., 80 Pa to 1000 Pa at 25° C., 90 Pa to 1000 Pa at 25° C., 100 Pa to 1000 Pa at 25° C., 200 Pa to 1000 Pa at 25° C., 300 Pa to 1000 Pa at 25° C., 400 Pa to 1000 Pa at 25° C., 500 Pa to 1000 Pa at 25° C., 600 Pa to 1000 Pa at 25° C., 700 Pa to 1000 Pa at 25° C., 800 Pa to 1000 Pa at 25° C., or 900 Pa to 1000 Pa at 25° C. In some embodiments, the molybdenum precursor has a crystalline phase ratio which is sufficient for the molybdenum precursor to have a vapor pressure of 1 Pa at 25° C., Pa at 25° C., 10 Pa at 25° C., 20 Pa at 25° C., 30 Pa at 25° C., 40 Pa at 25° C., 50 Pa at 25° C., 60 Pa at 25° C., 70 Pa at 25° C., 80 Pa at 25° C., 90 Pa at 25° C., 100 Pa at 25° C., 200 Pa at 25° C., 300 Pa at 25° C., 400 Pa at 25° C., 500 Pa at 25° C., 600 Pa at 25° C., 700 Pa at 25° C., 800 Pa at 25° C., 900 Pa at 25° C., or 1000 Pa at 25° C.

In some embodiments, a purity of the molybdenum precursor (e.g., the molybdenum pentachloride) is 90% to 99.9999%, or any range or subrange between 90% to 99.9999%. For example, in some embodiments, the purity of the molybdenum precursor is 91% to 99.9999%, 92% to 99.9999%, 93% to 99.9999%, 94% to 99.9999%, 95% to 99.9999%, 96% to 99.9999%, 97% to 99.9999%, 98% to 99.9999%, 99% to 99.9999%, 90% to 99.9%, 90% to 99.999%, or 90% to 99.999%.

### ASPECTS

Various Aspects are described below. It is to be understood that any one or more of the features recited in the following Aspect(s) can be combined with any one or more other Aspect(s).
Aspect 1. A method comprising:
   vaporizing, at a first temperature and a first pressure, a molybdenum reagent in a first vessel to obtain a vaporized molybdenum precursor;
   flowing the vaporized molybdenum precursor from the first vessel to a second vessel; and
   condensing, at a second temperature and a second pressure, the vaporized molybdenum precursor in the second vessel to obtain a molybdenum precursor,
      wherein the molybdenum precursor comprises a molybdenum pentachloride,
         wherein a crystalline phase ratio of the molybdenum pentachloride is sufficient for the molybdenum precursor to have a vapor pressure of 1 Pa to 1000 Pa at 25° C.
Aspect 2. The method according to Aspect 1, wherein the vaporizing comprises heating the first vessel under vacuum.
Aspect 3. The method of according to either Aspect 1 or 2, wherein:
   the first temperature is a temperature of 50° C. to 200° C.; and
   the first pressure is a pressure of 0.01 Torr to 100 Torr.
Aspect 4. The method according to any one of Aspects 1-3, wherein the condensing comprises cooling the second vessel under vacuum.
Aspect 5. The method according to any one of Aspects 1-4, wherein:
   the second temperature is a temperature of 50° C. to 200° C.; and
   the second pressure is a pressure of 0.01 Torr to 100 Torr.
Aspect 6. The method according to any one of Aspects 1-5, wherein:
   the first temperature is different from the second temperature; and
   the first pressure is different from the second pressure.
Aspect 7. A composition comprising:
   a molybdenum precursor comprising a molybdenum pentachloride,
      wherein a crystalline phase ratio of the molybdenum pentachloride is sufficient for the molybdenum precursor to have a vapor pressure of 1 Pa to 1000 Pa at 25° C.
Aspect 8. The composition according to Aspect 7, wherein the molybdenum precursor comprises triclinic molybdenum pentachloride crystals.
Aspect 9. The composition according to either Aspect 7 or 8, wherein the molybdenum precursor comprises monoclinic molybdenum pentachloride crystals.
Aspect 10. The composition according to any one of Aspects 7-9, wherein the molybdenum precursor comprises orthorhombic molybdenum pentachloride crystals.
Aspect 11. The composition according to any one of Aspects 7-10, wherein the molybdenum precursor comprises tetragonal molybdenum pentachloride crystals.
Aspect 12. The composition according to any one of Aspects 7-11, wherein the molybdenum precursor comprises hexagonal molybdenum pentachloride crystals.
Aspect 13. The composition according to any one of Aspects 7-12, wherein the molybdenum precursor comprises cubic molybdenum pentachloride crystals.
Aspect 14. A precursor vessel comprising:
   a molybdenum precursor comprising a molybdenum pentachloride,
      wherein a crystalline phase ratio of the molybdenum pentachloride is sufficient for the molybdenum precursor to have a vapor pressure of 1 Pa to 1000 Pa at 25° C.
Aspect 15. The precursor vessel according to Aspect 14, wherein the molybdenum precursor comprises triclinic molybdenum pentachloride crystals.
Aspect 16. The precursor vessel according to either Aspect 14 or 15, wherein the molybdenum precursor comprises monoclinic molybdenum pentachloride crystals.
Aspect 17. The precursor vessel according to any one of Aspects 14-16, wherein the molybdenum precursor comprises orthorhombic molybdenum pentachloride crystals.
Aspect 18. The precursor vessel according to any one of Aspects 14-17, wherein the molybdenum precursor comprises tetragonal molybdenum pentachloride crystals.
Aspect 19. The precursor vessel according to any one of Aspects 14-18, wherein the molybdenum precursor comprises hexagonal molybdenum pentachloride crystals.
Aspect 20. The precursor vessel according to any one of Aspects 14-19, wherein the molybdenum precursor comprises cubic molybdenum pentachloride crystals.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A method comprising:
vaporizing, at a first temperature and a first pressure, a molybdenum reagent in a first vessel to obtain a vaporized molybdenum precursor;
flowing the vaporized molybdenum precursor from the first vessel to a second vessel; and
condensing, at a second temperature and a second pressure, the vaporized molybdenum precursor in the second vessel to obtain a molybdenum precursor,
wherein the molybdenum precursor comprises a molybdenum pentachloride,
wherein a crystalline phase ratio of the molybdenum pentachloride is sufficient for the molybdenum precursor to have a vapor pressure of 1 Pa to 1000 Pa at 25° C.

2. The method of claim 1, wherein the vaporizing comprises heating the first vessel under vacuum.

3. The method of claim 1, wherein:
the first temperature is a temperature of 50° C. to 200° C.; and
the first pressure is a pressure of 0.01 Torr to 100 Torr.

4. The method of claim 1, wherein the condensing comprises cooling the second vessel under vacuum.

5. The method of claim 1, wherein:
the second temperature is a temperature of 50° C. to 200° C.; and
the second pressure is a pressure of 0.01 Torr to 100 Torr.

6. The method of claim 1, wherein:
the first temperature is different from the second temperature; and
the first pressure is different from the second pressure.

7. A composition comprising:
a molybdenum precursor comprising a molybdenum pentachloride,
wherein a crystalline phase ratio of the molybdenum pentachloride is sufficient for the molybdenum precursor to have a vapor pressure of 1 Pa to 1000 Pa at 25° C.

8. The composition of claim 7, wherein the molybdenum precursor comprises triclinic molybdenum pentachloride crystals.

9. The composition of claim 7, wherein the molybdenum precursor comprises monoclinic molybdenum pentachloride crystals.

10. The composition of claim 7, wherein the molybdenum precursor comprises orthorhombic molybdenum pentachloride crystals.

11. The composition of claim 7, wherein the molybdenum precursor comprises tetragonal molybdenum pentachloride crystals.

12. The composition of claim 7, wherein the molybdenum precursor comprises hexagonal molybdenum pentachloride crystals.

13. The composition of claim 7, wherein the molybdenum precursor comprises cubic molybdenum pentachloride crystals.

14. A precursor vessel comprising:
a molybdenum precursor comprising a molybdenum pentachloride,
wherein a crystalline phase ratio of the molybdenum pentachloride is sufficient for the molybdenum precursor to have a vapor pressure of 1 Pa to 1000 Pa at 25° C.

15. The precursor vessel of claim 14, wherein the molybdenum precursor comprises triclinic molybdenum pentachloride crystals.

16. The precursor vessel of claim 14, wherein the molybdenum precursor comprises monoclinic molybdenum pentachloride crystals.

17. The precursor vessel of claim 14, wherein the molybdenum precursor comprises orthorhombic molybdenum pentachloride crystals.

18. The precursor vessel of claim 14, wherein the molybdenum precursor comprises tetragonal molybdenum pentachloride crystals.

19. The precursor vessel of claim 14, wherein the molybdenum precursor comprises hexagonal molybdenum pentachloride crystals.

20. The precursor vessel of claim 14, wherein the molybdenum precursor comprises cubic molybdenum pentachloride crystals.
